(19) United States
(12) Patent Application Publication
(10) Pub. No.: US 2008/0185287 A1
(43) Pub. Date: Aug. 7, 2008

(54) SPUTTERING APPARATUS WITH ROTATABLE WORKPIECE CARRIER

(75) Inventor: GA-LANE CHEN, Santa Clara, CA (US)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/848,194

(22) Filed: Aug. 30, 2007

(30) Foreign Application Priority Data
Feb. 5, 2007 (TW) 096104071

(51) Int. Cl. C23C 14/35; C23C 14/00

(52) U.S. Cl. 204/298.07; 204/298.15

(57) ABSTRACT

An exemplary sputtering apparatus is provided. The sputtering apparatus includes a chamber, a workpiece carrier and at least a sputtering cathode. The chamber defines a sputtering cavity. Disposed in the sputtering cavity, the workpiece carrier includes a rotating disk and a plurality of rotating rods extending through and slidably engaged with the rotating disk. The rotating rods are configured for mounting multiple workpieces thereon and rotatable around a central axis of the rotating disk. The rotating rods are also rotatable around respective central axes of themselves. Disposed in the sputtering cavity, the sputtering cathode carries a target and is configured for sputtering the target material onto the workpieces on the rotating rods.

### BACKGROUND

1. Technical Field

The present invention relates generally to the field of sputtering technology, and more particularly, to a sputtering apparatus suitable for mass production.

2. Description of the Related Art

Sputtering is a physical vapor deposition (PVD) process whereby atoms in a solid target material are ejected into the gas phase due to bombardment of the material by energetic ions. With advantages such as good deposition efficiency, precise deposition control and relatively low cost, sputtering has become a popular deposition process in industry.

In a modern cell phone there is usually a camera module. In such camera modules, components such as lens barrel and lens seating generally have a small volume and a large quantity. It is often required to carry out sputtering on a large number of workpieces efficiently.

Therefore, what is needed is to provide a sputtering apparatus suitable for mass production.

### SUMMARY

A sputtering apparatus, in accordance with a preferred embodiment, is provided. The sputtering apparatus includes a chamber, a workpiece carrier and at least a sputtering cathode. The chamber defines a sputtering cavity. Disposed in the sputtering cavity, the workpiece carrier includes a rotating disk and a plurality of rotating rods extending through and slidably engaged with the rotating disk. The rotating rods are configured for mounting multiple workpieces thereon and rotatable around a central axis of the rotating disk. The rotating rods are also rotatable around respective central axes of themselves. Disposed in the sputtering cavity, the sputtering cathode carries a target and is configured for sputtering the target material onto the workpieces on the rotating rods.

The advantages and novel features will become more apparent from the following detailed description of embodiments when taken in conjunction with the accompanying drawings.

### BRIEF DESCRIPTION OF THE DRAWINGS

Many aspects of the present sputtering apparatus can be better understood with reference to the following drawings. The components in the drawings are not necessarily drawn to scale, the emphasis instead being placed upon clearly illustrating the principles of the present sputtering apparatus.

FIG. 1 is a schematically and partially cross-sectional view of a sputtering apparatus in accordance with a preferred embodiment, showing a chamber, a workpiece carrier and plural sputter cathodes;

FIG. 2 is a schematically and partially exploded view of the sputtering apparatus shown in FIG. 1;

FIG. 3 is a schematic exploded view of the workpiece carrier shown in FIG. 2;

FIG. 4 is a schematic top view of one of the sputter cathodes shown in FIG. 1.

### DETAILED DESCRIPTION OF THE EMBODIMENT

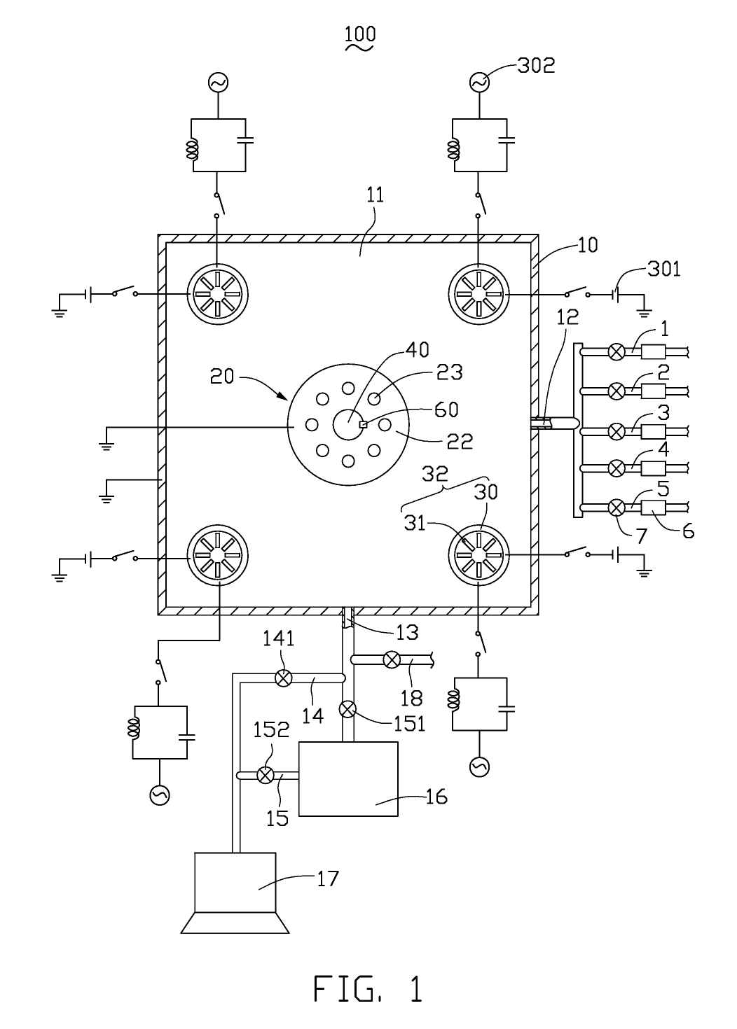

Referring to FIG. 1, a sputtering apparatus 100, in accordance with a preferred embodiment, includes a chamber 10, a workpiece carrier 20 and plural sputter cathodes 30.

The chamber 10 includes a sputtering cavity 11 defined therein, a gas entrance inlet 12, and a gas exit outlet 13. The gas entrance inlet 12 and the gas exit outlet 13 are respectively in communication with the sputtering cavity 11.

The gas entrance inlet 12 is connected to five gas inlet lines external to the chamber 10, namely a gas inlet line 1, a gas inlet line 2, a gas inlet line 3, a gas inlet line 4, and a gas inlet line 5, on each of which a mass flow rate controller (MFC) 6 and a valve 7 are disposed. In operation, gas inlet lines 1-5 are configured for receiving different kinds of gases into the chamber 10. For instance, the gas inlet line 1 is configured for receiving argon, krypton or helium gas. The gas inlet line 2 is configured for receiving oxygen gas. The gas inlet line 3 is configured for receiving nitrogen gas. The gas inlet line 4 is configured for receiving hydrogen, methane, or ethane gas. In the same way, the gas inlet line 5 is configured for receiving other kinds of gases into the chamber 10 as needed.

The gas exit outlet 13 is configured for vacuuming the sputtering cavity 11 before conducting vacuum sputtering with the sputtering apparatus chamber 100. Preferably, the gas exit outlet 13 is directly connected to a mechanical vacuum pump 17 by a gas outlet line 14, or alternatively, connected to the mechanical vacuum pump 17 by a line gas outlet line 15 and a high vacuum pump 16. The mechanical vacuum pump 17 is configured for exhausting gas in the chamber 10. The high vacuum pump 16 can be a turbine pump, a cryo pump, or a diffusion vacuum pump. A valve 141 is disposed on the gas outlet line 14. A valve 151 is disposed between the high vacuum pump 16 and the gas exit outlet 13. A valve 152 is disposed between the high vacuum pump 16 and the mechanical vacuum pump 17. In a vacuuming operation, the mechanical vacuum pump 17 is started and the gas outlet line 14 is opened. With the mechanical vacuum pump 17 vacuuming the sputtering cavity 11, the degree of vacuum in the sputtering cavity reaches about 100 Torr. Then the valve 141 is closed, the valve 151 and the valve 152 are opened, and the high vacuum pump 16 is started to vacuum the sputtering cavity 11 in cooperation with the mechanical vacuum pump 17. A turbine pump or cryo pump can be used to produce a vacuum of 5×10⁻⁶ Torr, or even a vacuum of 2×10⁻⁷ Torr in the sputtering cavity 11. A diffusion vacuum pump can be used to produce a vacuum of 5×10⁻⁵ Torr, or even a vacuum of 2×10⁻⁶ Torr in the sputtering cavity 11. The gas exit outlet 13 is connected with a gas feeding line 18. The gas feeding line 18 is configured for feeding nitrogen or dry clean air to the sputtering cavity 11 for preparing the chamber 10 to be opened after the sputtering process.

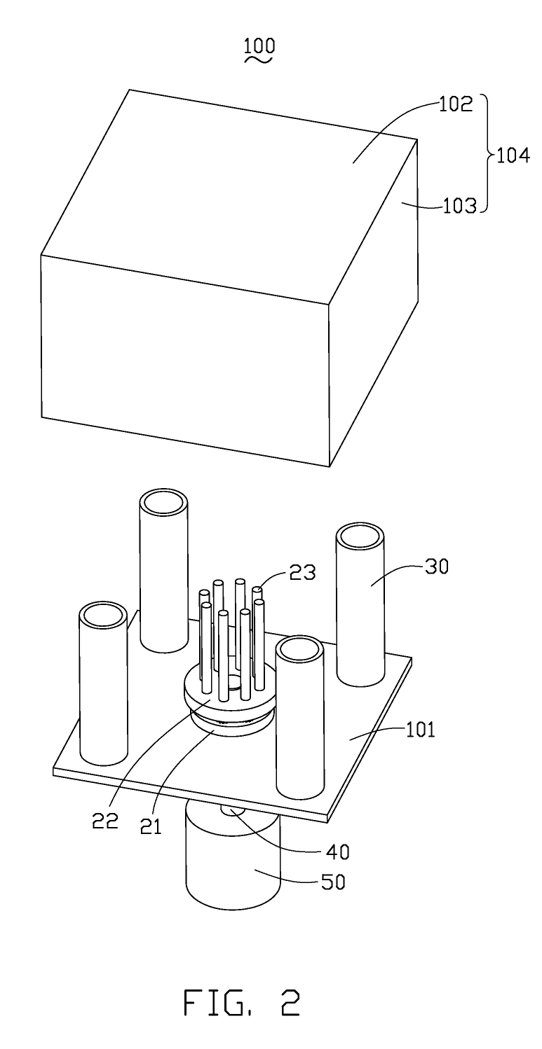

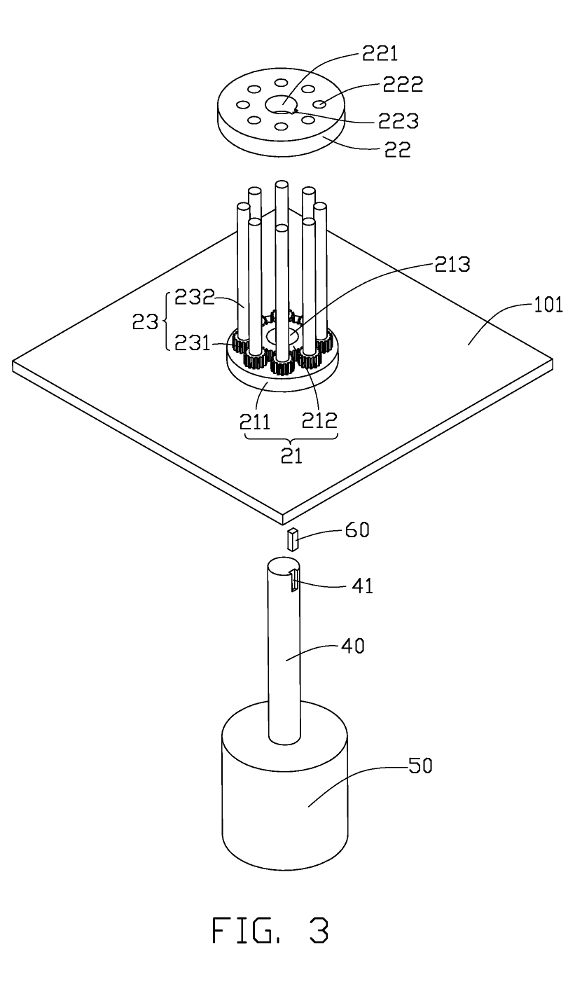

Referring to FIG. 2, for the purpose of illustrating the internal structure of the chamber 10, the chamber 10 is divided into a bottom part 101 and a cover part 104. The cover part 104 is formed by a top part 102 and sidewalls 103. The workpiece carrier 20 has a substrate 21, a rotating disk 22 and a number of rotating rods 23. The substrate 21 of the workpiece carrier 20 is fixed upon the bottom part 101 of the chamber 10. Referring to FIG. 3, the substrate 21 includes a base 211 and a gearing member 212. The base 211 and the gearing member 212 are integral with each other. A center hole 213 is formed on the substrate 21 for disposing a rotating shaft 40 through the substrate 21 and actuating the rotating disk 22 to rotate around a central axis of the rotating disk 22.

The rotating disk 22, having a center hole 221 and a number of through holes 222 is disposed above the substrate 21. The center hole 221 is configured for disposing the rotating shaft 40 through the rotating disk 22 and actuating the rotating disk 22 to rotate around the central axis of the rotating disk. The through hole 222 is configured for disposing the multiple rotating rods 23 through the rotating disk 22. In this embodiment, an axial notch 41 is disposed on a top of the rotating shaft 40. Correspondingly, an axial notch 223 is disposed on an inner wall of the center hole 221 of the rotating disk 22. After the rotating shaft 40 is inserted into the center hole 213 on the substrate 21 and the center hole 221 on the rotating disk 22, the axial notch 41 on the rotating shaft 40 is engaged to the axial notch 223 on the rotating disk 22 by a bolt 60. By this means, the rotating disk 22 can be actuated by the rotating shaft 40 to rotate around the central axis of the rotating disk 22. It is understood there are other ways to actuate the rotating disk 22 by the rotating shaft 40. The rotating shaft 40 can be driven by an actuator 50 to rotate. Preferably the actuator 50 is a motor.

The multiple rotating rods 23 are uniformly arranged are uniformly arranged along an imaginary circle around the gearing member 212 of the substrate 21, penetrating the rotating disk 22 through the through holes 222 and slidably engaged with inner sidewalls of the through holes 222 respectively. In this embodiment, there are 8 rotating rods altogether. Each one of the rotating rods 23 has a bottom part 231 and a top part 232. The outer radius of the bottom part 231 is greater than the outer radius of the top part 232. The bottom part 231 has a gear portion meshing with the gearing member 212 of the substrate 21 and rotatably contacting the base 211 of the substrate 21. When the rotating disk 22, driven by the rotating shaft 40, actuates the rotating rods 23 to rotate around the central axis of the rotating disk 22, the rotating rods 23 are simultaneously forced to rotate around their own respective center axes. In other words, the rotating rods 23 can rotate along with the rotating disk 22 and simultaneously rotate around the respective center axes of the rotating rods 23. A bottom part 231 of the rotating rod 23 is connected to and in contact with the base 211 of the substrate 21. It is understood that the base 211 can be eliminated and the gearing member 212 and the bottom part 231 can be in direct contact with the bottom part 101 of the chamber 10. The rotating rods 23 are configured for hanging workpieces being sputtered. Preferably, the workpiece can be a cylindrical item such as a lens barrel or a lens seating, usually covered and fixed on the rotating rod 23 to achieve good uniformity.

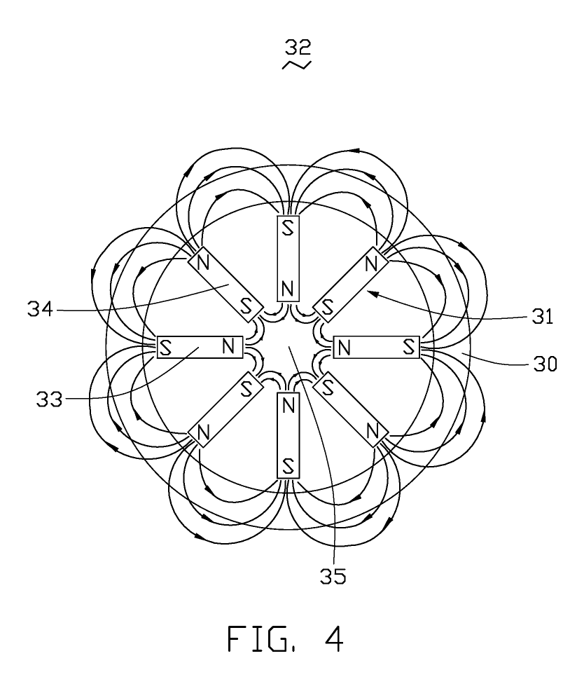

The sputtering apparatus 100 has four sputtering cathodes 32 disposed around the workpiece carrier 20 on the bottom part 101 of the chamber 10. Preferably, the four sputtering cathodes 32 are disposed symmetrically to each other with respect to the workpiece carrier 20 and configured to rotate respectively around the center axes of the sputtering cathodes 32. Each of the sputtering cathodes 32 carries a target 30 to be sputtered on the workpiece. The sputtering cathodes 32 can be connected to a direct current (DC) power source 301 for direct current (DC) sputtering when the target is a conductor, or alternatively with a radio frequency (RF) power source 302 for radio frequency sputtering (RF sputtering) when the target material is an insulator or a semiconductor. Referring to FIG. 4, a magnetron 31 having multiple, for example, eight pieces of magnets is disposed in the center of each sputtering cathode 32 for facilitating ionization of gases around the target 30, increasing the probability of collision between gas ions and the target 30 and hence improving the speed of sputtering. Preferably, the multiple magnets are radially disposed in a way that any two neighboring magnetic poles have magnetization polarities opposite to each other. In this embodiment, the magnetron 31 has a central axis 35 and plural first and second magnets 33 and 34 surrounding the central axis 35 in an alternate fashion. The first and second magnets 33 and 34 are arranged in a manner that the north poles of the first magnets 33 face toward the central axis 35 and the north poles of the second magnets 34 face away from the central axis 35. The four sputtering cathodes 32 can respectively carry targets of different materials and be connected with a power source simultaneously or sequentially. When multiple sputtering cathodes 32 are connected to a power source simultaneously, the sputtering apparatus can be configured to conduct co-sputtering whereby an alloy film is deposited on the workpiece. When multiple sputtering cathodes 32 are connected to a power source sequentially, a multi-layer film can be deposited on the workpiece.

In above preferred embodiment, the sputtering apparatus 100 includes a number of rotating rods 23 configured for hanging a large number of small workpiece so that a large number of workpieces can be sputtered simultaneously. By this means, a relatively high efficiency is achieved. In addition, the rotating rods 23 can not only rotate along with the rotating disk 22 but also simultaneously rotate around the respective center axes of the rotating rods 23 so that the uniformity of the film sputtered on the workpieces is improved.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the present invention.

What is claimed is:

1. A sputtering apparatus, comprising:
a chamber defining a sputtering cavity;
a workpiece carrier disposed in the sputtering cavity, the workpiece carrier comprising a rotating disk and a plurality of rotating rods extending through and slidably engaged with the rotating disk, the rotating rods being configured for mounting a plurality of workpieces thereon, and being rotatable around a central axis of the rotating disk and rotatable around respective central axes of the rotating rods; and
at least a sputtering cathode for carrying a target material disposed in the sputtering cavity and configured for sputtering the target material onto the workpieces on the rotating rods.

2. The sputtering apparatus of claim 1, wherein the plurality of rotating rods are uniformly arranged along an imaginary circle centered at the central axis of the rotating disk.

3. The sputtering apparatus of claim 1, wherein the workpiece carrier further comprises a gearing member disposed on a bottom part of the chamber, the plurality of rotating rods being arranged around the gearing member and having a gear portion meshing with the gearing member, the rotating disk being above the gearing member and rotatable by a shaft extending through the gearing member.

4. The sputtering apparatus of claim 3, wherein the workpiece carrier further comprises a base disposed between the gearing member and the bottom part of the chamber, the gearing member being fixed on the base, the rotating rods coming into contact with and being rotatable relative to the base.

5. The sputtering apparatus of claim 4, wherein the base and the gearing member are integral with each other.

6. The sputtering apparatus of claim 3, wherein the gearing member is fixed on the bottom part of the chamber, the plurality of rotating rods coming into contact with and being rotatable relative to the bottom part of the chamber.

7. The sputtering apparatus of claim 1, wherein the chamber has a gas entrance inlet and a gas exit outlet both in communication with the sputtering cavity, the gas entrance inlet is configured for feeding working gases into the chamber.

8. The sputtering apparatus of claim 1, wherein the at least a sputtering cathode respectively has a magnetron being disposed therein.

9. The sputtering apparatus of claim 8, wherein the plurality of sputter cathodes are uniformly disposed around the rotating disk.

10. The sputtering apparatus of claim 8, wherein the magnetron comprises multiple pieces of magnets, the magnets being radially disposed.

11. A sputtering apparatus, comprising:
a chamber having a sputtering cavity and a mounting base therein;
a workpiece carrier disposed in the sputtering cavity and mounted on the mounting base, the workpiece carrier comprising a rotating disk and a plurality of parallel rotating rods for mounting workpieces thereon, the rotating rods being jointly rotatable with the rotating disk, and being rotatable around respective longitudinal central axes thereof; and
a plurality of sputter cathodes disposed in the sputtering cavity and surrounding the workpiece carrier.

12. The sputtering apparatus of claim 11, wherein each of the sputter cathodes comprises a magnetron having a central axis and a plurality of first and second magnets surrounding the central axis, the first and second magnets being arranged in a manner that north poles of the first magnets face toward the central axis, north poles of the second magnets face away from the central axis, and the first and second magnets are arranged to surround the central axis in an alternate fashion.

13. The sputtering apparatus of claim 12, wherein each of the sputter cathodes is rotatable about the central axis of the magnetron.

14. The sputtering apparatus of claim 12, wherein the magnets include at least one of permanent magnets and electromagnets.

15. The sputtering apparatus of claim 11, wherein the workpiece carrier further comprises a gearing member disposed on the mounting base, and each of the rotating rods has a gear portion meshing with the gear member.

16. The sputtering apparatus of claim 15, wherein the rotating disk has a plurality of through holes with the rotating rods extending therethrough.
